(19) United States
(12) Patent Application Publication
(10) Pub. No.: US 2024/0232483 A1
(43) Pub. Date: Jul. 11, 2024

(54) Method And Device For Grouping Layout Layer, And Electronic Device And Non-transitory Storage Medium

(71) Applicant: Cellixsoft Corporation, Beijing (CN)

(72) Inventors: Ke DING, Beijing (CN); Chongxi ZHANG, Beijing (CN); Yanyan ZHOU, Beijing (CN)

(21) Appl. No.: 18/389,548

(22) Filed: Nov. 14, 2023

(30) Foreign Application Priority Data
Jan. 9, 2023 (CN) 202310029733.7

(51) Int. Cl. G06F 30/31

(52) U.S. Cl. CPC G06F 30/31

(57) ABSTRACT

Disclosed in the present disclosure are a method for grouping layout layer and apparatus, and an electronic device and a non-transitory storage medium. The method includes: determining a first layout layer, where the first layout layer is a layer to be grouped; determining a second layout layer, determining a target layout layer group according to a preset grouping rule, layer information of the first layout layer, and layer information of the second layout layer, and adding the first layout layer to the target layout layer group.

### TECHNICAL FIELD

The present disclosure relates to the technical field of electronic design automation, and in particular to a method and device for grouping layout layer, and an electronic device and a non-transitory storage medium.

### BACKGROUND

In production processes, a plurality of layout layers with different functions are often required during the process of integrated circuit design. At present, in most of the design software, all the layout layers are displayed tiled, a user needs to check relevant layout layers by dragging a scroll bar up and down in a software layer label page during checking and using, which cannot quickly and effectively find a target layout layer, and there are often a plurality of layout layers with similar names in the layer label page, such that it is inclined to select the wrong layout layer during layout design. In addition, most of the design software does not support bulk operations on the layout layers, resulting in problems such as inefficiency in drawing and modifying the layout design during designing of integrated circuits.

In view of the above problems, no effective solution has been proposed yet.

### SUMMARY

An aspect of embodiments of the present disclosure provides a method for grouping layout layer, which includes: determining a first layout layer, where the first layout layer is a layer to be grouped; determining a second layout layer; determining a target layout layer group according to a preset grouping rule, layer information of the first layout layer, and layer information of the second layout layer; and adding the first layout layer to the target layout layer group.

In some embodiments, the layer information includes at least one of the following: a layer type and grouping information, where the layer type includes a reference layer and a conventional layer; the grouping information is used for indicating a layout layer associated with the first layout layer or the second layout layer.

In some embodiments, in a case that the preset grouping rule is a first-type grouping rule, determining the target layout layer group according to the preset grouping rule, the layer information of the first layout layer, and the layer information of the second layout layer includes: in a case that the layer type of the second layout layer is the reference layer, determining the grouping information of the first layout layer, wherein the grouping information of the first layout layer is used for indicating a fourth layout layer that has been associated with the first layout layer; in a case that the grouping information of the first layout layer indicates that the fourth layout layer does not exist, establishing an association relationship between the first layout layer and the second layout layer, and determining a layout layer group where the second layout layer is located as the target layout layer group; and in a case that the grouping information of the first layout layer indicates that the fourth layout layer exists, deleting an association relationship between the first layout layer and the fourth layout layer, establishing the association relationship between the first layout layer and the second layout layer, and determining the layout layer group where the second layout layer is located as the target layout layer group.

In some embodiments, in a case that the preset grouping rule is a second-type grouping rule, determining the target layout layer group according to the preset grouping rule, the layer information of the first layout layer, and the layer information of the second layout layer includes: in a case that the layer type of the second layout layer is a non-reference layer, modifying the layer type of the second layout layer to the reference layer; after the layer type of the second layout layer is modified to the reference layer, determining the grouping information of the first layout layer, where the grouping information of the first layout layer is used for indicating a fourth layout layer that has been associated with the first layout layer; in a case that the grouping information of the first layout layer indicates that the fourth layout layer does not exist, establishing an association relationship between the first layout layer and the second layout layer, and determining a layout layer group where the second layout layer is located as the target layout layer group; and in a case that the grouping information of the first layout layer indicates that the fourth layout layer exists, deleting an association relationship between the first layout layer and the fourth layout layer, establishing the association relationship between the first layout layer and the second layout layer, and determining the layout layer group where the second layout layer is located as the target layout layer group.

In some embodiments, in a case that the preset grouping rule is a third-type grouping rule, determining the target layout layer group according to the preset grouping rule, the layer information of the first layout layer, and the layer information of the second layout layer includes: in a case that the grouping information of the second layout layer indicates that a third layout layer exists, establishing an association relationship between the first layout layer and the third layout layer, and determining a layout layer group where the third layout layer is located as the target layout layer group.

In some embodiments, establishing the association relationship between the first layout layer and the third layout layer includes: determining the grouping information of the first layout layer, where the grouping information of the first layout layer is used for indicating a fourth layout layer that has been associated with the first layout layer; in a case that the grouping information of the first layout layer indicates that the fourth layout layer does not exist, establishing the association relationship between the first layout layer and the third layout layer; and in a case that the grouping information of the first layout layer indicates that the fourth layout layer exists, deleting an association relationship between the first layout layer and the fourth layout layer, and establishing the association relationship between the first layout layer and the third layout layer.

In some embodiments, in a case that the preset grouping rule is a fourth-type grouping rule, determining the target layout layer group according to the preset grouping rule, the layer information of the first layout layer, and the layer information of the second layout layer includes: in a case that the layer type of the second layout layer is the reference layer, determining the grouping information of the first layout layer, where the grouping information of the first layout layer is used for indicating a fourth layout layer that has been associated with the first layout layer; in a case that the grouping information of the first layout layer indicates that the fourth layout layer does not exist, establishing an association relationship between the first layout layer and the second layout layer, and determining a layout layer group where the second layout layer is located as the target layout layer group; and in a case that the grouping information of the first layout layer indicates that the fourth layout layer exists, establishing the association relationship between the first layout layer and the second layout layer, and determining both the layout layer group where the second layout layer is located and a layout layer group where the fourth layout layer is located as the target layout layer groups.

In some embodiments, in a case that the preset grouping rule is a fifth-type grouping rule, determining the target layout layer group according to the preset grouping rule, the layer information of the first layout layer, and the layer information of the second layout layer includes: in a case that the layer type of the second layout layer is a non-reference layer, modifying the layer type of the second layout layer to the reference layer; in a case that the layer type of the second layout layer is the reference layer, determining the grouping information of the first layout layer, where the grouping information of the first layout layer is used for indicating a fourth layout layer that has been associated with the first layout layer; in a case that the grouping information of the first layout layer indicates that the fourth layout layer does not exist, establishing an association relationship between the first layout layer and the second layout layer, and determining a layout layer group where the second layout layer is located as the target layout layer group; and in a case that the grouping information of the first layout layer indicates that the fourth layout layer exists, establishing the association relationship between the first layout layer and the second layout layer, and determining both the layout layer group where the second layout layer is located and a layout layer group where the fourth layout layer is located as the target layout layer groups.

In some embodiments, in a case that the preset grouping rule is a sixth-type grouping rule, determining the target layout layer group according to the preset grouping rule, the layer information of the first layout layer, and the layer information of the second layout layer includes: in a case that the grouping information of the second layout layer indicates that a third layout layer exists, establishing an association relationship between the first layout layer and the third layout layer, and determining a layout layer group where the third layout layer is located as the target layout layer group.

In some embodiments, establishing the association relationship between the first layout layer and the third layout layer, and determining the layout layer group where the third layout layer is located as the target group includes: determining the grouping information of the first layout layer, where the grouping information of the first layout layer is used for indicating a fourth layout layer that has been associated with the first layout layer; in a case that the grouping information of the first layout layer indicates that the fourth layout layer does not exist, establishing the association relationship between the first layout layer and the third layout layer, and determining the layout layer group where the third layout layer is located as the target layout layer group; and in a case that the grouping information of the first layout layer indicates that the fourth layout layer exists, establishing the association relationship between the first layout layer and the third layout layer, and determining both the layout layer group where the third layout layer is located and a layout layer group where the fourth layout layer is located as the target layout layer groups.

In some embodiments, after the first layout layer is added to the target layout layer group, the layout layer grouping method further includes: performing a bulk operation on at least two associated layout layers in the target layout layer.

In some embodiments, after the first layout layer is added to the target layout layer group, the layout layer grouping method further includes: performing an operation on at least one associated layout layer in the target layout layer.

Another aspect of embodiments of the present disclosure further provides a device for grouping layout layer, which includes: a first processing component, configured to determine a first layout layer, wherein the first layout layer is a layer to be grouped; a second processing component, configured to determine a second layout layer; a selection component, configured to determine a target layout layer group according to a preset grouping rule, layer information of the first layout layer, and layer information of the second layout layer; and a third processing component, configured to add the first layout layer to the target layout layer group.

Another aspect of an embodiment of the present disclosure further provides an electronic device. The electronic device includes a processor; the processor is configured to run a program; and the layout layer grouping method is performed when the program is run.

Another aspect of an embodiment of the present disclosure further provides a non-transitory storage medium. The non-transitory storage medium includes a stored computer program. A device where the non-transitory storage medium is located performs the layout layer grouping method by running the computer program.

### BRIEF DESCRIPTION OF THE DRAWINGS

The drawings described herein are used to provide a further understanding of the present disclosure, and constitute a part of the present disclosure. The exemplary embodiments of the present disclosure and the description thereof are used to explain the present disclosure, but do not constitute improper limitations to the present disclosure. In the drawings:

FIG. 1 is a schematic flowchart of a method for grouping layout layer according to embodiments of the present disclosure.

FIG. 2 is a schematic diagram of a layout layer list in the related art according to embodiments of the present disclosure.

FIG. 3 is a schematic diagram of layout layers with similar names in the related art according to embodiments of the present disclosure.

FIG. 4 is a schematic flowchart of a method for obtaining a reference layer by creating a new layout layer according to embodiments of the present disclosure.

FIG. 5 is a schematic flowchart of a method for obtaining a reference layer by modifying a layer type of an existing layout layer according to embodiments of the present disclosure.

FIG. 6 is a schematic flowchart of a first-type grouping rule according to embodiments of the present disclosure.

FIG. 7 is a schematic flowchart of a second-type grouping rule according to embodiments of the present disclosure.

FIG. 8 is a schematic flowchart of a third-type grouping rule according to embodiments of the present disclosure.

FIG. 9 is a schematic flowchart of a fourth-type grouping rule according to embodiments of the present disclosure.

FIG. 10 is a schematic flowchart of a fifth-type grouping rule according to embodiments of the present disclosure.

FIG. 11 is a schematic flowchart of a sixth-type grouping rule according to embodiments of the present disclosure.

FIG. 12 is a schematic flowchart of an operation of obtaining a reference layer by creating a new layout layer in software according to embodiments of the present disclosure.

FIG. 13 is a schematic diagram of a reference layer obtained by creating a new layout layer according to embodiments of the present disclosure.

FIG. 14 is a schematic diagram of parameter settings for creation of reference layers in batches according to embodiments of the present disclosure.

FIG. 15 is a schematic diagram of a result of creation of reference layers in batches according to embodiments of the present disclosure.

FIG. 16 is a schematic flowchart of an operation of obtaining a reference layer by modifying a layer type of an existing layout layer in software according to embodiments of the present disclosure.

FIG. 17 is a schematic flowchart of an operation of grouping a plurality of conventional layers to an existing reference layer according to embodiments of the present disclosure.

FIG. 18 is a schematic flowchart of an operation of setting the grouping of a plurality of conventional layers to a plurality of existing reference layers according to embodiments of the present disclosure.

FIG. 19 is a schematic flowchart of an operation of setting the grouping of a reference layer to another reference layer according to embodiments of the present disclosure.

FIG. 20 is a schematic diagram of implementation of layout layer grouping through dragging in a case that a preset grouping rule is default+update according to embodiments of the present disclosure.

FIG. 21 is a schematic diagram of implementation of layout layer grouping through dragging in a case that a preset grouping rule is post-creation+update according to embodiments of the present disclosure.

FIG. 22 is a schematic diagram of implementation of layout layer grouping through dragging in a case that a preset grouping rule is inheritance+update according to embodiments of the present disclosure.

FIG. 23 is another schematic diagram of implementation of layout layer grouping through dragging in a case that a preset grouping rule is inheritance+update according to embodiments of the present disclosure.

FIG. 24 is a schematic diagram of implementation of layout layer grouping through dragging in a case that a preset grouping rule is inheritance+addition according to embodiments of the present disclosure.

FIG. 25 is a schematic diagram of automatic implementation of layout layer grouping according to embodiments of the present disclosure.

FIG. 26 is another schematic diagram of automatic implementation of layout layer grouping according to embodiments of the present disclosure.

FIG. 27 is a schematic diagram of implementation of layout layer grouping through a text definition form according to embodiments of the present disclosure.

FIG. 28 is a schematic diagram of a layer folding effect according to embodiments of the present disclosure.

FIG. 29 is a schematic diagram of an effect of displaying elements on all layers according to embodiments of the present disclosure.

FIG. 30 is a schematic diagram of a display effect after elements on all layers under CUTS and CONTACTS groups are hidden according to embodiments of the present disclosure.

FIG. 31 is a schematic diagram of a display effect after elements on all layers under a METALS group are hidden according to embodiments of the present disclosure.

FIG. 32 is a schematic flowchart of an operation of modifying the attributes of conventional layers in a reference layer group in batches according to embodiments of the present disclosure.

FIG. 33 is a schematic flowchart of an operation of setting the sizes of through holes in batches according to embodiments of the present disclosure.

FIG. 34 is a schematic diagram of a core increment effect according to embodiments of the present disclosure.

FIG. 35 is a schematic flowchart of an operation of performing sorting according to names of reference layers according to embodiments of the present disclosure.

FIG. 36 is a schematic diagram of the drawing of a layout pattern in the related art according to embodiments of the present disclosure.

FIG. 37 is a schematic diagram of the drawing of a layout pattern in a preset mode according to embodiments of the present disclosure.

FIG. 38 is another schematic diagram of the drawing of a layout pattern in a preset mode according to embodiments of the present disclosure.

FIG. 39 is a schematic diagram of a layout pattern after a position offset and a size increment of a pattern according to embodiments of the present disclosure.

FIG. 40 is a schematic diagram of another layout pattern after a position offset and a size increment of a pattern according to embodiments of the present disclosure.

FIG. 41 is a schematic structural diagram of a layout layer grouping apparatus according to embodiments of the present disclosure.

FIG. 42 is a block diagram of a hardware structure of a computer terminal (or an electronic device) configured to implement a method for grouping layout layer according to embodiments of the present disclosure.

### DETAILED DESCRIPTION OF THE EMBODIMENTS

In order to enable those skilled in the art to better understand the solutions of the present disclosure, the technical solutions in the embodiments of the present disclosure will be clearly and completely described below in combination with the drawings in the embodiments of the present disclosure. It is apparent that the described embodiments are only part of the embodiments of the present disclosure, not all the embodiments. All other embodiments obtained by those of ordinary skill in the art on the basis of the embodiments in the present disclosure without creative work shall fall within the scope of protection of the present disclosure.

It is to be noted that terms “first”, “second” and the like in the description, claims and the above-mentioned drawings of the present disclosure are used for distinguishing similar objects rather than describing a specific sequence or a precedence order. It should be understood that the data used in such a way may be exchanged where appropriate, in order that the embodiments of the present disclosure described here can be implemented in an order other than those illustrated or described herein. In addition, terms “include” and “have” and any variations thereof are intended to cover non-exclusive inclusions. For example, it is not limited for processes, methods, systems, products or devices containing a series of steps or units to clearly list those steps or units, and other steps or units which are not clearly listed or are inherent to these processes, methods, products or devices may be included instead.

In most of the design software in the related art, all layout layers in layout design software are displayed tiled, and a user needs to check relevant layout layers by dragging a scroll bar up and down in a software layer label page during checking and using, often resulting in the following problems.

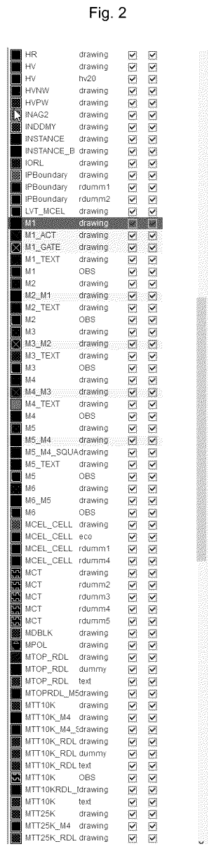

Problem 1, there are too many layout layers, such that a target layout layer cannot be rapidly and effectively found. FIG. 2 is a schematic diagram of a layout layer list in the related art according to an embodiment of the present disclosure. As shown in FIG. 2, only some of the layout layers are listed in FIG. 2 here, and the number of layout layers in real projects often far exceeds the number of layout layers in FIG. 2. HR, HV, and the like at the first column in FIG. 2 are all customized layout names, and drawing, hv20, and the like at the second column are used for representing functions of the layout layers.

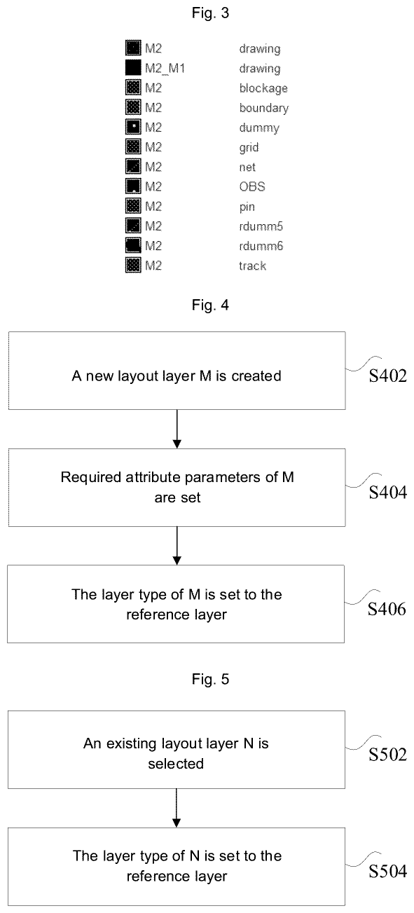

Problem 2, on a layout database (especially advanced process), there are often a plurality of layout layers with similar names, such that it is easy to select the wrong layout layer during layout design. FIG. 3 is a schematic diagram of layout layers with similar names in the related art according to an embodiment of the present disclosure. As shown in FIG. 3, during practical production, each layer has a different function, such that the layers cannot be used at will during drawing of layouts. The layouts need to be clearly distinguished during drawing; and if the layouts are used incorrectly, failed validation is caused in subsequent processes. For example, in a case that a second metal wire layer is drawn, M2(drawing) in FIG. 3 is not used, but an M2(OBS) layout layer in FIG. 3 is used by mistake, resulting in incorrect exported data, such that the data cannot pass the check validation.

Problem 3, at present, in a case that an integrated circuit is designed, a plurality of layout layers are often used. However, in a case that a bulk operation needs to be performed on the layout layers in the related art, a user needs to determine the layout layer to be processed from the plurality of layout layers by himself each time, resulting in low working efficiency of the user.

In order to solve the above problems, embodiments of the present disclosure provides a method for grouping layout layer embodiment. It is to be noted that the steps shown in the flowchart of the accompanying drawings may be executed in a computer system, such as a set of computer-executable instructions, and although a logical sequence is shown in the flowchart, in some cases, the steps shown or described may be executed in a different order than here.

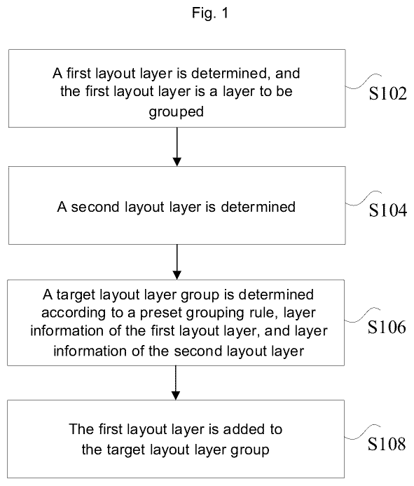

FIG. 1 is a schematic flowchart of a method for grouping layout layer according to an embodiment of the present disclosure. As shown in FIG. 1, the method includes the following steps.

At S102, a first layout layer is determined, and the first layout layer is a layer to be grouped.

At S104, a second layout layer is determined.

At S106, a target layout layer group is determined according to a preset grouping rule, layer information of the first layout layer, and layer information of the second layout layer.

At S108, the first layout layer is added to the target layout layer group.

In some embodiments of the present disclosure, after the first layout layer is added to the target layout layer group, the method for grouping layout layer further includes: performing a bulk operation on at least two associated layout layers in the target layout layer group; or performing an operation on at least one associated layout layer in the target layout layer group.

In some embodiments of the present disclosure, in a case that a target layout layer group is used as a reference layer, it is actually a layout layer that may be individually operated, and other layout layers in the target layout layer group may also be operated in batches through a certain iconic layout layer.

In some embodiments of the present disclosure, the layer information of the second layout layer includes at least one of the following: a layer type of the second layout layer, and grouping information of the second layout layer. The layer type includes a reference layer and a conventional layer; the grouping information of the second layout layer is used for indicating a third layout layer associated with the second layout layer; and the grouping information of the second layout layer may also be the second layout layer.

In some embodiments, the layout layer has two attribute parameters of “the layer type” and “the grouping information”; and “the layer type” may be the conventional layer or the reference layer. “The grouping information” may be null or at least one layout layer. As an optional implementation, the attribute parameter of “the grouping information” may be set by the name or identifier of the layout layer.

In some embodiments, different preset grouping rules may be formed according to whether the current layout layer to be grouped already has the grouping information and whether another layout layer is the reference layer or has the grouping information. Details are described below.

For ease of expression, the first layout layer is a layout layer B to be grouped; the second layout layer is another layout layer A; the third layout layer is a layout layer C in the existing grouping information of the layout layer A; and the fourth layout layer is a layout layer D in the existing grouping information of the layout layer B. It is to be noted that, both the layout layers A and B may be one or more layout layers; and C and D may be 0 or a plurality of layout layers. For ease of expression, In some embodiments, one layout layer is used as an example for description.

In a case that the layout type of the layout layer is the reference layer, the layout layer corresponds to a group. The group may be understood as a layout layer set. The layout layer of which layer type is the reference layer may be regarded as the set. By means of the layout layer of which layer type is the reference layer, a bulk operation may be performed on the layout layers in the set. In addition, the layout layer of which layer type is the reference layer also has all features and functions of the layout layer of which layer type is the conventional layer. That is, the layout layer of which layer type is the reference layer is also an independent layout layer.

The layout layer of which layer type is the reference layer may be obtained in advance through two methods.

One method is to create a new layout layer and modify the layer type to the reference layer. Specifically, FIG. 4 is a schematic flowchart of a method for obtaining a reference layer by creating a new layout layer according to an embodiment of the present disclosure. As shown in FIG. 4, the method includes the following steps.

At S402, a new layout layer M is created.

At S404, required attribute parameters of M are set.

At S406, the layer type of M is set to the reference layer.

The required attribute parameters mentioned in S404 generally include layer names, display styles, GDSII numbers, pixel widths, etc., which represent that the reference layer has all features and functions of the conventional layer.

Another method is to select the layout layer of which layer type is already the conventional layer, and modify the layer type to the reference layer. FIG. 5 is a schematic flowchart of a method for obtaining a reference layer by modifying a layer type of an existing layout layer according to an embodiment of the present disclosure. As shown in FIG. 5, the method includes the following steps.

At S502, an existing layout layer N is selected.

At S504, the layer type of N is set to the reference layer.

In some embodiments of the present disclosure, in a case that the preset grouping rule is a first-type grouping rule, determining the target layout layer group according to the preset grouping rule, the layer information of the first layout layer, and the layer information of the second layout layer includes: in a case that the layer type of the second layout layer is the reference layer, determining the grouping information of the first layout layer, wherein the grouping information of the first layout layer is used for indicating a fourth layout layer that has been associated with the first layout layer; in a case that the grouping information of the first layout layer indicates that the fourth layout layer does not exist, establishing an association relationship between the first layout layer and the second layout layer, and determining a layout layer group where the second layout layer is located as the target layout layer group; and in a case that the grouping information of the first layout layer indicates that the fourth layout layer exists, deleting an association relationship between the first layout layer and the fourth layout layer, establishing the association relationship between the first layout layer and the second layout layer, and determining the layout layer group where the second layout layer is located as the target layout layer group.

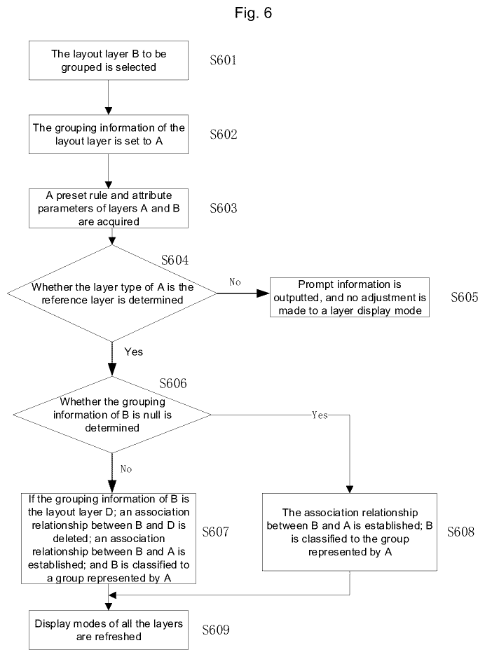

In some embodiments, the first-type grouping rule is a “default+update” rule. Specifically, FIG. 6 is a schematic flowchart of a first-type grouping rule according to an embodiment of the present disclosure. As shown in FIG. 6, the flow includes the following steps.

At S601, the layout layer B to be grouped is selected.

At S602, the grouping information of the layout layer is set to the layout layer A.

At S603, a preset rule and attribute parameters of layers A and B are acquired.

At S604, whether the layer type of A is the reference layer is determined.

At S605, in a case that the layer type of A is not the reference layer, prompt information is outputted, no adjustment is made to a layer display mode, and the flow is ended.

At S606, in a case that the layer type of A is the reference layer, whether the previous grouping information of B is null is determined.

At S607, in a case that the grouping information of B is not null, if the grouping information of B is the layout layer D; an association relationship between B and D is deleted; an association relationship between B and A is established; B is classified to a group represented by A; and then S609 is performed.

At S608, in a case that the grouping information of B is null, the association relationship between B and A is established; B is classified to the group represented by A; and then S609 is performed.

At S609, display modes of all the layers are refreshed.

In some embodiments of the present disclosure, in a case that the preset grouping rule is a second-type grouping rule, determining the target layout layer group according to the preset grouping rule, the layer information of the first layout layer, and the layer information of the second layout layer includes: in a case that the layer type of the second layout layer is a non-reference layer, modifying the layer type of the second layout layer to the reference layer; in a case that the layer type of the second layout layer is the reference layer, determining the grouping information of the first layout layer, where the grouping information of the first layout layer is used for indicating a fourth layout layer that has been associated with the first layout layer; in a case that the grouping information of the first layout layer indicates that the fourth layout layer does not exist, establishing an association relationship between the first layout layer and the second layout layer, and determining a layout layer group where the second layout layer is located as the target layout layer group; and in a case that the grouping information of the first layout layer indicates that the fourth layout layer exists, deleting an association relationship between the first layout layer and the fourth layout layer, establishing the association relationship between the first layout layer and the second layout layer, and determining the layout layer group where the second layout layer is located as the target layout layer group.

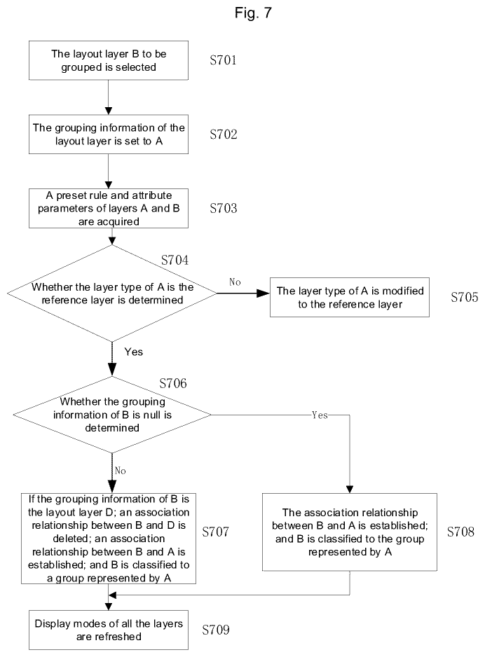

In some embodiments, the second-type grouping rule is a “post-creation+update” rule. Specifically, FIG. 7 is a schematic flowchart of a second-type grouping rule according to an embodiment of the present disclosure. As shown in FIG. 7, the flow includes the following steps.

At S701, the layout layer B to be grouped is selected.

At S702, the grouping information of the layout layer is set to the layout layer A.

At S703, a preset rule and attribute parameters of layers A and B are acquired.

At S704, whether the layer type of A is the reference layer is determined.

At S705, in a case that the layer type of A is not the reference layer, the layer type of A is modified to the reference layer, S706 is performed.

At S706, in a case that the layer type of A is the reference layer, whether the previous grouping information of B is null is determined.

At S707, in a case that the grouping information of B is not null, if the grouping information of B is the layout layer D; an association relationship between B and D is deleted; an association relationship between B and A is established; B is classified to a group represented by A; and then S709 is performed.

At S708, in a case that the grouping information of B is null, the association relationship between B and A is established; B is classified to the group represented by A; and then S709 is performed.

At S709, display modes of all the layers are refreshed.

In some embodiments of the present disclosure, in a case that the preset grouping rule is a third-type grouping rule, determining the target layout layer group according to the preset grouping rule, the layer information of the first layout layer, and the layer information of the second layout layer includes: in a case that the grouping information of the second layout layer indicates that a third layout layer exists, establishing an association relationship between the first layout layer and the third layout layer, and determining a layout layer group where the third layout layer is located as the target layout layer group.

In some embodiments of the present disclosure, establishing the association relationship between the first layout layer and the third layout layer includes: determining the grouping information of the first layout layer, where the grouping information of the first layout layer is used for indicating a fourth layout layer that has been associated with the first layout layer; in a case that the grouping information of the first layout layer indicates that the fourth layout layer does not exist, establishing the association relationship between the first layout layer and the third layout layer; and in a case that the grouping information of the first layout layer indicates that the fourth layout layer exists, deleting an association relationship between the first layout layer and the fourth layout layer, and establishing the association relationship between the first layout layer and the third layout layer.

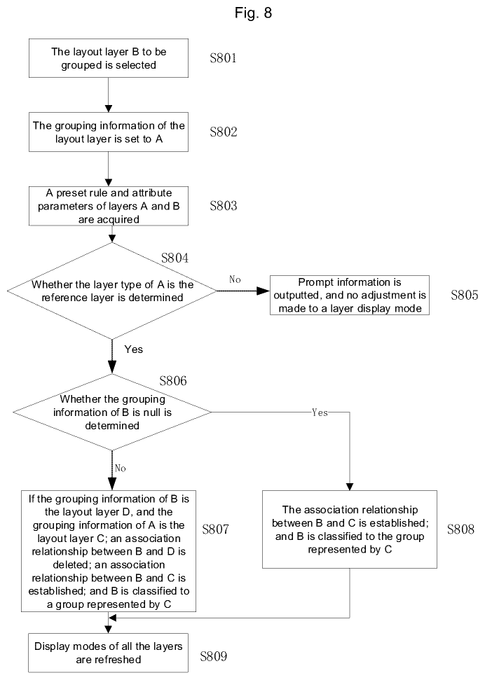

In some embodiments, the third-type grouping rule is an “inheritance+update” rule. Specifically, FIG. 8 is a schematic flowchart of a third-type grouping rule according to an embodiment of the present disclosure. As shown in FIG. 8, the flow includes the following steps.

At S801, the layout layer B to be grouped is selected.

At S802, the grouping information of the layout layer is set to the layout layer A.

At S803, a preset rule and attribute parameters of layers A and B are acquired.

At S804, whether the grouping information of A is null is determined.

At S805, in a case that the grouping information of A is null, prompt information is outputted, no adjustment is made to a layer display mode, and the flow is ended.

At S806, in a case that the grouping information of A is not null, whether the previous grouping information of B is null is determined.

At S807, in a case that the grouping information of B is not null, if the grouping information of B is the layout layer D, and the grouping information of A is the layout layer C; an association relationship between B and D is deleted; an association relationship between B and C is established; B is classified to a group represented by C; and then S809 is performed.

At S808, in a case that the grouping information of B is null, the association relationship between B and C is established; B is classified to the group represented by C; and then S809 is performed.

At S809, display modes of all the layers are refreshed.

In some embodiments of the present disclosure, in a case that the preset grouping rule is a fourth-type grouping rule, determining the target layout layer according to the preset grouping rule, the layer information of the first layout layer, and the layer information of the second layout layer includes: in a case that the layer type of the second layout layer is the reference layer, determining the grouping information of the first layout layer, where the grouping information of the first layout layer is used for indicating a fourth layout layer that has been associated with the first layout layer; in a case that the grouping information of the first layout layer indicates that the fourth layout layer does not exist, establishing an association relationship between the first layout layer and the second layout layer, and determining a layout layer group where the second layout layer is located as the target layout layer group; and in a case that the grouping information of the first layout layer indicates that a layout layer that has been associated with the first layout layer exists, establishing the association relationship between the first layout layer and the second layout layer, and determining both the layout layer group where the second layout layer is located and a layout layer group where the fourth layout layer is located as the target layout layer groups.

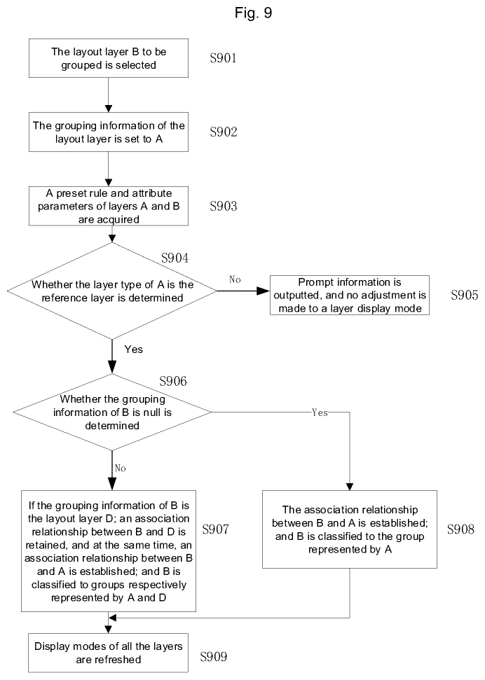

In some embodiments, the fourth-type grouping rule is a “default+addition” rule. Specifically, FIG. 9 is a schematic flowchart of a fourth-type grouping rule according to an embodiment of the present disclosure. As shown in FIG. 9, the flow includes the following steps.

At S901, the layout layer B to be grouped is selected.

At S902, the grouping information of the layout layer is set to the layout layer A.

At S903, a preset rule and attribute parameters of layers A and B are acquired.

At S904, whether the layer type of A is the reference layer is determined.

At S905, in a case that the layer type of A is not the reference layer, prompt information is outputted, no adjustment is made to a layer display mode, and the flow is ended.

At S906, in a case that the layer type of A is the reference layer, whether the previous grouping information of B is null is determined.

At S907, in a case that the grouping information of B is not null, if the grouping information of B is the layout layer D; an association relationship between B and D is retained, and at the same time, an association relationship between B and A is established; B is classified to groups respectively represented by A and D; and then S909 is performed.

At S908, in a case that the grouping information of B is null, the association relationship between B and A is established; B is classified to the group represented by A; and then S909 is performed.

At S909, display modes of all the layers are refreshed.

In some embodiments of the present disclosure, in a case that the preset grouping rule is a fifth-type grouping rule, determining the target layout layer according to the preset grouping rule, the layer information of the first layout layer, and the layer information of the second layout layer includes: in a case that the layer type of the second layout layer is a non-reference layer, modifying the layer type of the second layout layer to the reference layer; in a case that the layer type of the second layout layer is the reference layer, determining the grouping information of the first layout layer, where the grouping information of the first layout layer is used for indicating a fourth layout layer that has been associated with the first layout layer; in a case that the grouping information of the first layout layer indicates that the fourth layout layer does not exist, establishing an association relationship between the first layout layer and the second layout layer, and determining a layout layer group where the second layout layer is located as the target layout layer group; and in a case that the grouping information of the first layout layer indicates that the fourth layout layer exists, establishing the association relationship between the first layout layer and the second layout layer, and determining both the layout layer group where the second layout layer is located and a layout layer group where the fourth layout layer is located as the target layout layer groups.

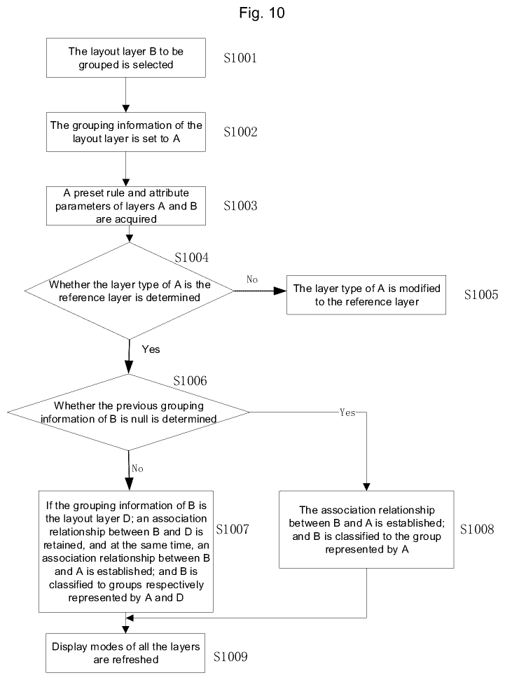

In some embodiments, the fifth-type grouping rule is a “post-creation+addition” rule. Specifically, FIG. 10 is a schematic flowchart of a fifth-type grouping rule according to an embodiment of the present disclosure. As shown in FIG. 10, the flow includes the following steps.

At S1001, the layout layer B to be grouped is selected.

At S1002, the grouping information of the layout layer is set to the layout layer A.

At S1003, a preset rule and attribute parameters of layers A and B are acquired.

At S1004, whether the layer type of A is the reference layer is determined.

At S1005, in a case that the layer type of A is not the reference layer, the layer type of A is modified to the reference layer, S1006 is performed.

At S1006, in a case that the layer type of A is the reference layer, whether the previous grouping information of B is null is determined.

At S1007, in a case that the grouping information of B is not null, if the grouping information of B is the layout layer D; an association relationship between B and D is retained, and at the same time, an association relationship between B and A is established; B is classified to groups respectively represented by A and D; and then S1009 is performed.

At S1008, in a case that the grouping information of B is null, the association relationship between B and A is established; B is classified to the group represented by A; and then S1009 is performed.

At S1009, display modes of all the layers are refreshed.

In some embodiments of the present disclosure, in a case that the preset grouping rule is a sixth-type grouping rule, determining the target layout layer according to the preset grouping rule, the layer information of the first layout layer, and the layer information of the second layout layer includes: in a case that the grouping information of the second layout layer indicates that a third layout layer exists, establishing an association relationship between the first layout layer and the third layout layer, and determining a layout layer group where the third layout layer is located as the target layout layer group.

In some embodiments of the present disclosure, establishing the association relationship between the first layout layer and the third layout layer, and determining the layout layer group where the third layout layer is located as the target group includes: determining the grouping information of the first layout layer, where the grouping information of the first layout layer is used for indicating a fourth layout layer that has been associated with the first layout layer; in a case that the grouping information of the first layout layer indicates that the fourth layout layer does not exist, establishing the association relationship between the first layout layer and the third layout layer, and determining the layout layer group where the third layout layer is located as the target layout layer group; and in a case that the grouping information of the first layout layer indicates that the fourth layout layer exists, establishing the association relationship between the first layout layer and the third layout layer, and determining both the layout layer group where the third layout layer is located and a layout layer group where the fourth layout layer is located as the target layout layer groups.

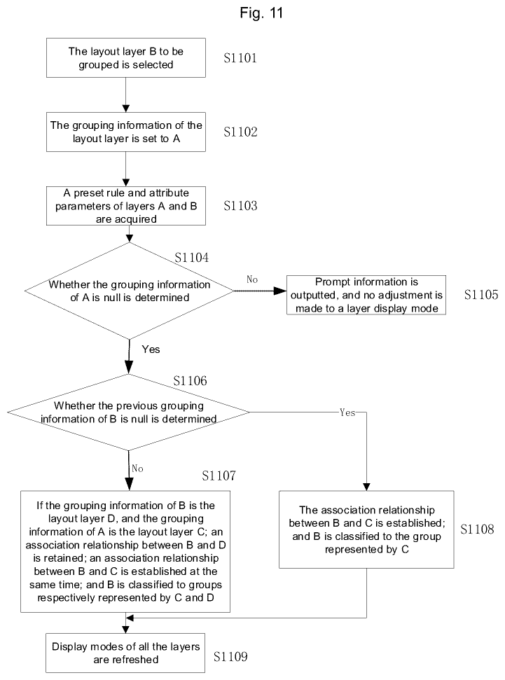

In some embodiments, the sixth-type grouping rule is an “inheritance+update” rule. Specifically, FIG. 11 is a schematic flowchart of a sixth-type grouping rule according to an embodiment of the present disclosure. As shown in FIG. 11, the flow includes the following steps.

At S1101, the layout layer B to be grouped is selected.

At S1102, the grouping information of the layout layer is set to the layout layer A.

At S1103, a preset rule and attribute parameters of layers A and B are acquired.

At S1104, whether the grouping information of A is null is determined.

At S1105, in a case that the grouping information of A is null, prompt information is outputted, no adjustment is made to a layer display mode, and the flow is ended.

At S1106, in a case that the grouping information of A is not null, whether the previous grouping information of B is null is determined.

At S1107, in a case that the grouping information of B is not null, if the grouping information of B is the layout layer D, and the grouping information of A is the layout layer C; an association relationship between B and D is retained; an association relationship between B and C is established at the same time; B is classified to groups respectively represented by C and D; and then S1109 is performed.

At S1108, in a case that the grouping information of B is null, the association relationship between B and C is established; B is classified to the group represented by C; and then S1109 is performed.

At S1109, display modes of all the layers are refreshed.

In some embodiments, the above default, post-creation and inheritance are different processes on A. Specifically, the above default is used for representing the case where A is not the preset reference layer, then new grouping information of B should not include A. The post-creation is used for representing the case where A is not the preset reference layer, in a case that the new grouping information of B includes A, the layer type of A may be automatically set to the reference layer. The inheritance is used for representing the case where A is not used as the new grouping information of B, but existing grouping information C of A is used as the new grouping information of B. The update and addition are different processes on final grouping of the layer B to be grouped. Specifically, the update is used for representing the case where the original grouping information D of B is not retained, and a grouping result of B is updated according to the current grouping situation. The addition is used for representing the case where the original grouping information D of B is retained, and the current grouping situation is added to the grouping result of B. The preset grouping rules above are combinations of different situations.

The method for grouping layout layer in S102 to S108 in the embodiments of the present disclosure is further introduced.

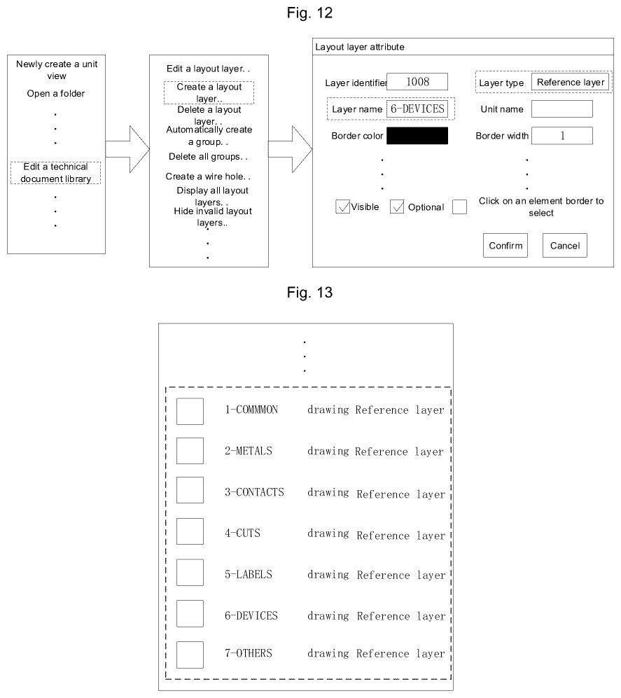

In some embodiments, for the method for obtaining the reference layer by creating a new layout layer shown in FIG. 4, creating the layout layer and modifying attribute information of the layout layer while creating may specifically implemented in software of this embodiment through the following operations as shown in FIG. 12.

FIG. 12 is a schematic flowchart of an operation of obtaining a reference layer by creating a new layout layer in software according to an embodiment of the present disclosure, includes: right click a technical document library→edit the technical document library→display, at a main window of the software, layout layer information of the technical document library→right click to select creation of a layout layer→manually input required attribute parameters such as layer names, and select a layer type as a reference layer.

FIG. 13 is a schematic diagram of a reference layer obtained by creating a new layout layer according to an embodiment of the present disclosure. As shown in FIG. 13, steps in FIG. 12 are repeated, such that the reference layers in dashed boxes in FIG. 13 may be generated one by one. 1-COMMON, 2-METALS, 3-CONTACTS, 4-CUTS, 5-LABELS, 6-DEVICES, and 7-OTHERS are all customized layer names.

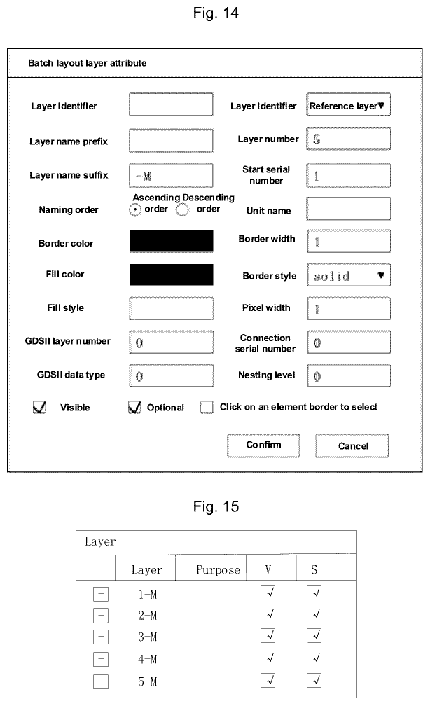

In a case that a plurality of reference layers need to be created, a batch creation method may be used. Specifically, in a case that the batch creation method is selected, the prefixes and suffixes of the layer names may be specified, a number of layers required to be created is specified, and the software automatically creates the specified number of reference layers in an ascending or descending order. The number of layers is determined by users. FIG. 14 is a schematic diagram of parameter settings for creation of reference layers in batches according to embodiments of the present disclosure. Settings are shown in FIG. 14. FIG. 15 is a schematic diagram of a result of creation of reference layers in batches according to an embodiment of the present disclosure. An effect after batch creation is shown in FIG. 15. 1-M, 2-M, 3-M, 4-M, and 5-M are all layout names automatically created.

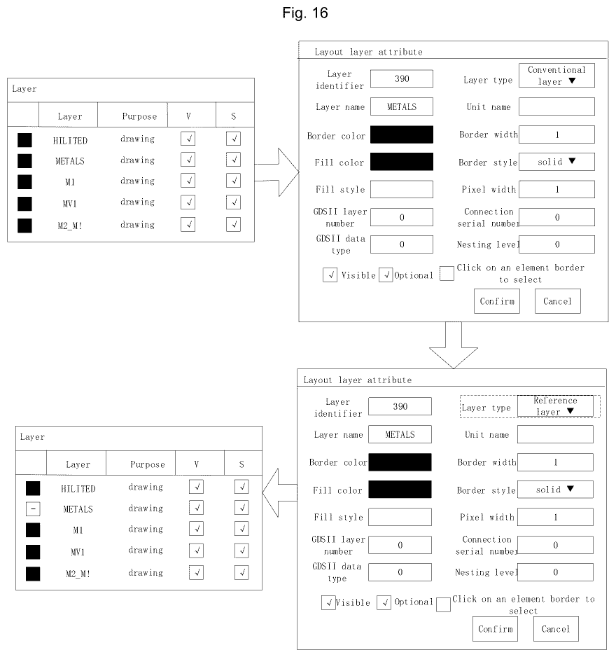

In some embodiments, the method for obtaining the reference layer by modifying a layer type of an existing layout layer shown in FIG. 5 may be specifically implemented in the software of this embodiment through the following operations. FIG. 16 is a schematic flowchart of an operation of obtaining a reference layer by modifying a layer type of an existing layout layer in software according to an embodiment of the present disclosure. As shown in FIG. 16, the method includes the following steps.

At least one existing conventional layout layer is selected; layer attribute parameter information is acquired, including layer names, display styles, sizes of default patterns, etc.; and the layer type is modified from the conventional layer to the reference layer, and the layer is regarded as the reference layer and may be associated with another reference layer and conventional layer.

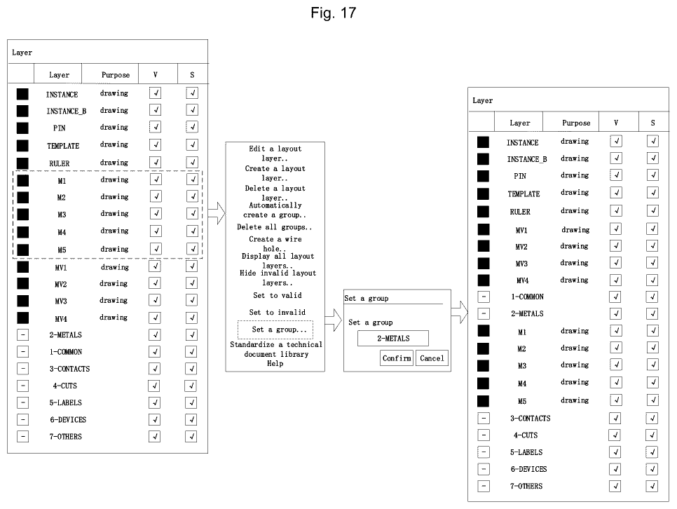

In some embodiments, a plurality of conventional layers may be grouped to an existing reference layer. Specifically, FIG. 17 is a schematic flowchart of an operation of grouping a plurality of conventional layers to an existing reference layer according to an embodiment of the present disclosure. As shown in FIG. 17, operations in the software include the following: a layout layer panel→select at least one conventional layer (M1-M5 in this example) required to be placed in the same group→set a group, and input the layout layer name. 2-METALS in this example is the pre-established reference layer.

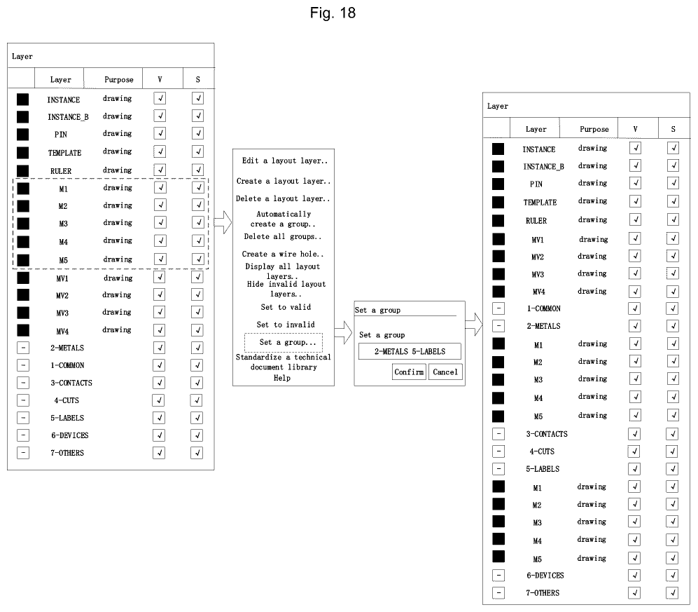

In some embodiments, the plurality of conventional layers may be grouped to a plurality of existing reference layers. FIG. 18 is a schematic flowchart of an operation of setting the grouping of a plurality of conventional layers to a plurality of existing reference layers according to an embodiment of the present disclosure. As shown in FIG. 18, operations in the software include the following: a layout layer panel→select at least one conventional layer (M1-M5 in this example) required to be placed in the same group→set a group, and input the layout layer name. 2-METALS and 5-LABELS in this example are the pre-established reference layers.

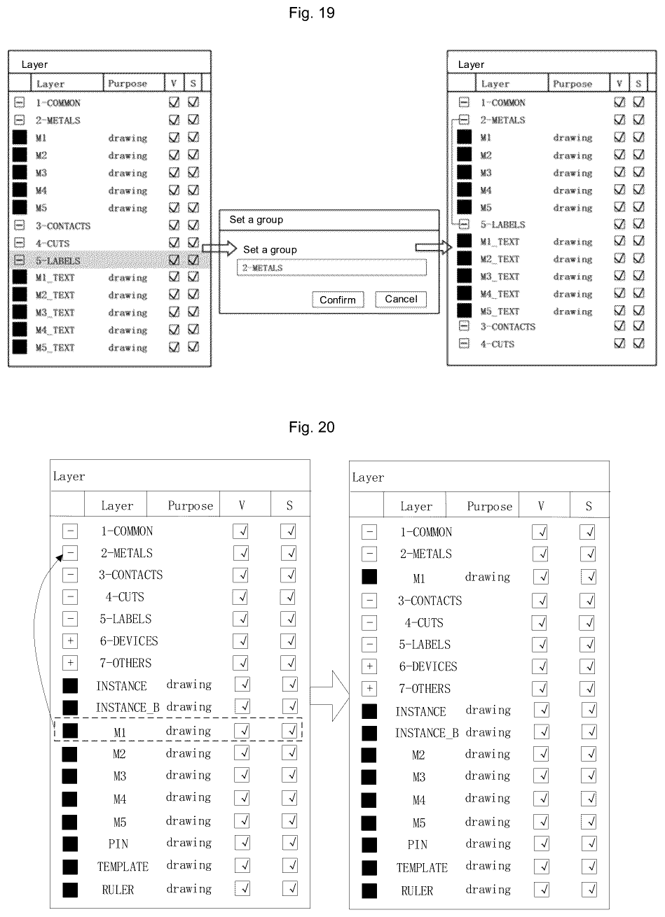

In some embodiments, the reference layer may be grouped to another reference layer. FIG. 19 is a schematic flowchart of an operation of setting the grouping of a reference layer to another reference layer according to an embodiment of the present disclosure. As shown in FIG. 19, operations in the software include the following: a layout layer panel→select the reference layer to be grouped (5-LABELS in this example, M1_TEXT-M5_TEXT are conventional layers associated with 5-LABELS)→set a group, and input the layout layer name. 2-METALS in this example is the pre-established reference layer (M1-M5 are conventional layers associated with 2-METALS), as shown in FIG. 19. After grouping is completed, 5-LABELS is associated with 2-METALS.

In some embodiments, the grouping of layout layers may be implemented through dragging. FIG. 20 is a schematic diagram of implementation of layout layer grouping through dragging in a case that a preset grouping rule is default+update according to an embodiment of the present disclosure. As shown in FIG. 20, the conventional layer M1 is dragged to the reference layer 2-METALS; and in a case that the preset grouping rule is default+update, an association relationship between M1 and 2-METALS is established, and M1 is grouped to 2-METALS.

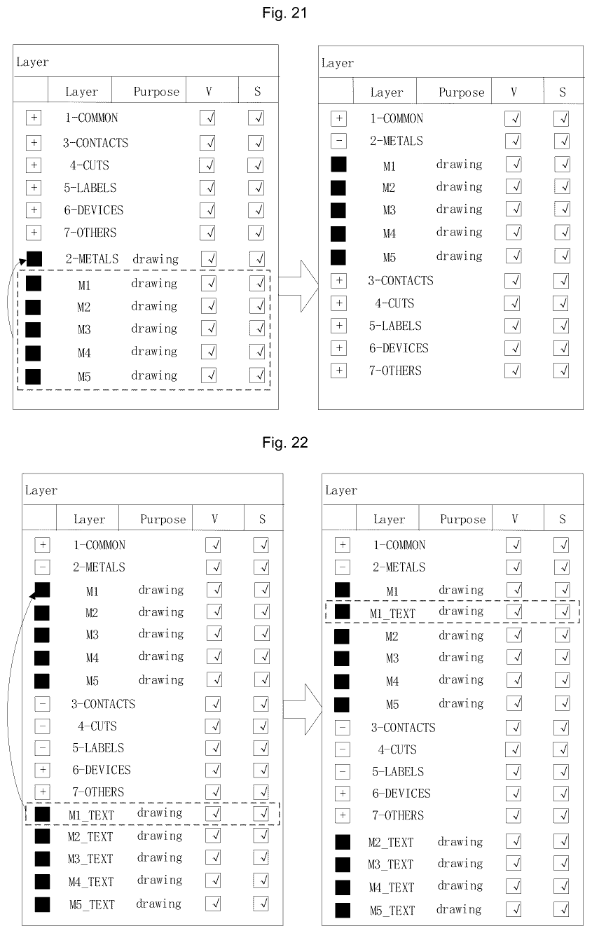

In some embodiments, the grouping of layout layers may be implemented through dragging. FIG. 21 is a schematic diagram of implementation of layout layer grouping through dragging in a case that a preset grouping rule is post-creation+update according to an embodiment of the present disclosure. As shown in FIG. 21, the conventional layers M1-M5 are dragged to the conventional layer 2-METALS; and in a case that the grouping rule is post-creation+update, the layer type of 2-METALS is set to the reference layer, the grouping information of M1-M5 is set to 2-METALS, and grouping is completed; and M1-M5 are folded and displayed to 2-METALS.

In some embodiments, the grouping of layout layers may be implemented through dragging. FIG. 22 is a schematic diagram of implementation of layout layer grouping through dragging in a case that a preset grouping rule is inheritance+update according to an embodiment of the present disclosure. As shown in FIG. 22, the conventional layer M1_TEXT is dragged to the conventional layer M1 that has been grouped; and in a case that the preset grouping rule is inheritance+update, the grouping information of the M1_TEXT layer inherits the grouping information of the M1 layer, an association relationship between M1_TEXT and 2-METALS is established, and M1_TEXT is grouped to 2-METALS.

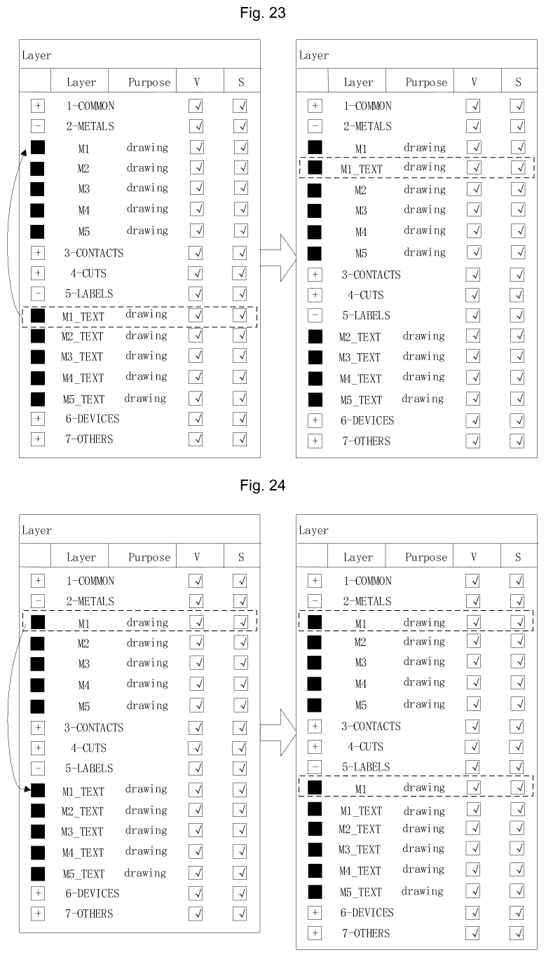

As optional implementations, the grouping of layout layers may be implemented through dragging. FIG. 23 is another schematic diagram of implementation of layout layer grouping through dragging in a case that a preset grouping rule is inheritance+update according to an embodiment of the present disclosure. As shown in FIG. 23, the conventional layer M1_TEXT under a reference layer 5-LABELS group is dragged to the conventional layer M1 that has been grouped; and in a case that the preset grouping rule is inheritance+update, the grouping information of the M1_TEXT layer inherits the grouping information of the M1 layer, the association relationship between M1_TEXT and 2-METALS is established, M1_TEXT is grouped to 2-METALS, and the layout layer M1_TEXT does no longer exist under the 5-LABELS group.

In some embodiments, the grouping of layout layers may be implemented through dragging. FIG. 24 is a schematic diagram of implementation of layout layer grouping through dragging in a case that a preset grouping rule is inheritance+addition according to an embodiment of the present disclosure. As shown in FIG. 24, the conventional layer M1 under a reference layer 2-METALS group is dragged to the conventional layer M1_TEXT under the reference layer 5-LABELS group; and in a case that the preset grouping rule is inheritance+addition, the grouping information of the M1_TEXT layer is added to the grouping information of the M1 layer, the association relationship between M1 and 5-LABELS is established, the association relationship between M1 and 2-METALS is retained, and M1 is grouped to 2-METALS and 5-LABELS.

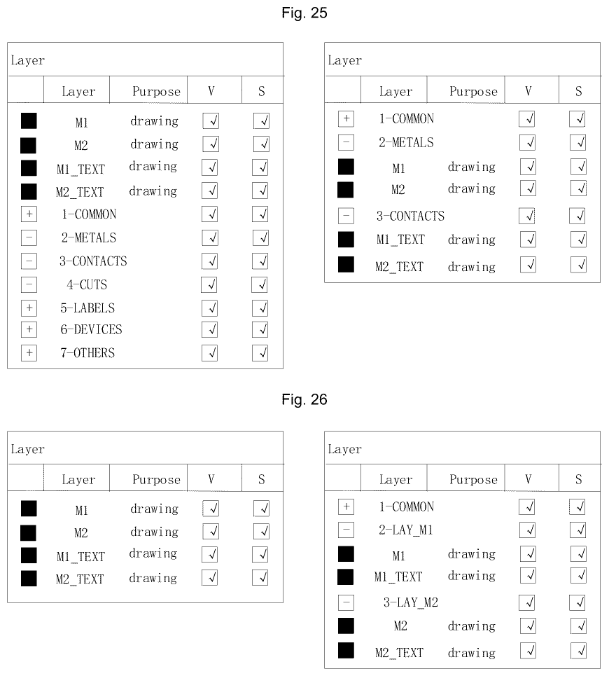

In some embodiments, the grouping of layout layers may be implemented through dragging. FIG. 25 is a schematic diagram of automatic implementation of layout layer grouping according to an embodiment of the present disclosure. As shown in FIG. 25, the conventional layers M1, M2, M1_TEXT, and M2_TEXT are layout layers to be grouped. In a case that automatic grouping is selected, the features of these layers are extracted through an algorithm to automatically match the features of the existing reference layers. And the grouping information of the layout layers to be grouped is modified to the reference layers of which features are matched, so as to complete grouping.

In some embodiments, name suffix words of the layout layers to be grouped are extracted through an algorithm, and perform semantic matching with the names of the existing reference layers. Then the grouping information of M1_TEXT and M2_TEXT with suffixes is modified to the existing reference layer 3-LABELS. And grouping attributes of M1 and M2 with no suffixes are modified to 2-METALS.

In some embodiments, the grouping of layout layers may be implemented through dragging. FIG. 26 is another schematic diagram of automatic implementation of layout layer grouping according to an embodiment of the present disclosure. As shown in FIG. 26, the conventional layers M1, M2, M1_TEXT, and M2_TEXT are layout layers to be grouped. Automatic grouping is selected. The features of these layers are extracted through an algorithm. New reference layers are created. And the grouping information of the layout layers to be grouped is modified to the newly-created reference layers, so as to complete grouping.

In some embodiments, name prefix words of the layout layers to be grouped are extracted through an algorithm; two reference layers 2-LAY_M1 and 3-LAY_M2 are automatically created; and grouping attributes of M1 and M1_TEXT are modified to 2-LAY_M1, and M2 and M2_TEXT are modified to 3-LAY_M2.

In some embodiments, the grouping of layout layers may be implemented through a text definition form, and the grouping of the layout layers may be defined with a text form. The software automatically sets the grouping information of the layout layers and creates the corresponding reference layers according to document content. FIG. 27 is a schematic diagram of implementation of layout layer grouping through a text definition form according to embodiments of the present disclosure. As shown in FIG. 27, there are several conventional layers and reference layers before the layout layers are grouped. Through a layout layer definition document, the grouping information of each conventional layer is determined. And an association relationship between the conventional layer and the corresponding reference layer is established, so as to complete the grouping of the layout layers.

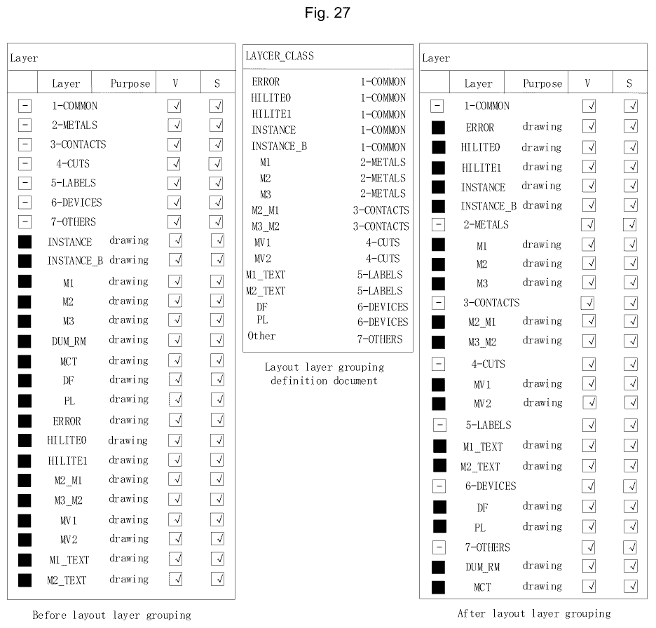

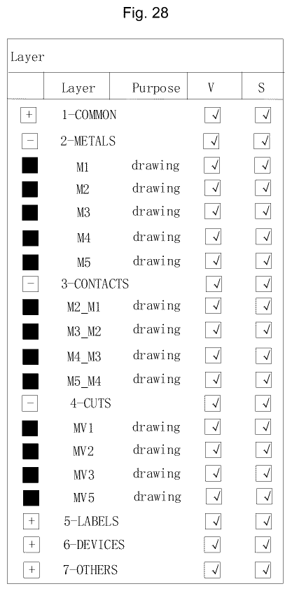

In some embodiments, the conventional layer may be displayed in folding and unfolding manners. FIG. 28 is a schematic diagram of a layer folding effect according to an embodiment of the present disclosure. As shown in FIG. 28, “+/−” before the reference layer is clicked or the name of the reference layer is double-clicked, such that the conventional layer under the group may be displayed in folding and unfolding manners. It may be set to unfold a specific group, and fold the specific group.

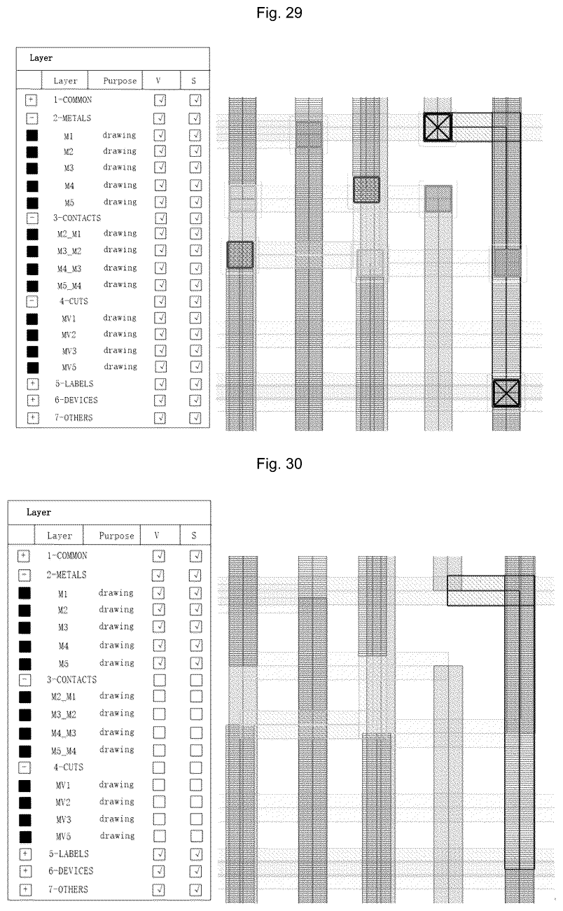

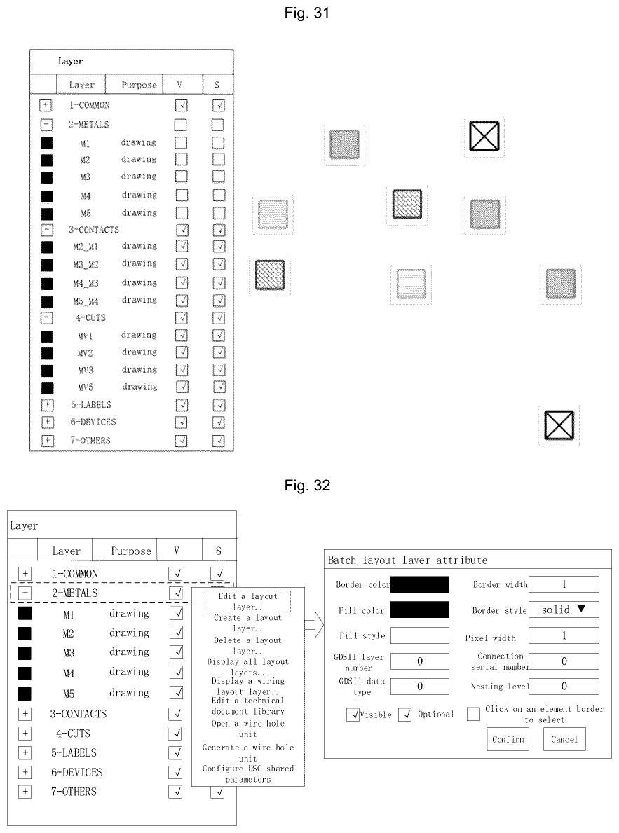

In some embodiments, elements on the layer may be displayed or hidden in batches. For example, the elements on the layer may be hidden or displayed by clicking a check box corresponding3ed by clicking “V” check boxes of the conventional layer one by one. In the present disclosure, by clicking the check box of the reference layer, the elements on all the layers under the group are hidden/displayed. FIG. 29 is a schematic diagram of an effect of displaying elements on all layers according to an embodiment of the present disclosure. FIG. 30 is a schematic diagram of a display effect after elements on all layers under 4-CUTS and 3-CONTACTS groups are hidden according to an embodiment of the present disclosure. FIG. 31 is a schematic diagram of a display effect after elements on all layers under a 2-METALS group are hidden according to an embodiment of the present disclosure.

In addition, In some embodiments, as shown in FIG. 15, the elements on the layer may or may not be selected by clicking a check box corresponding to “S” after the layer.

In some embodiments, the attributes of the conventional layers in the reference layer group may be modified in batches. FIG. 32 is a schematic flowchart of an operation of modifying the attributes of conventional layers in a reference layer group in batches according to an embodiment of the present disclosure. As shown in FIG. 32, colors, fills, widths, and the like may be modified in batches. Select a certain reference layer→right click→edit a layout layer→adjust a display mode (colors, fills, and widths) of the layout layer→set a uniform display style for the layout layers in the same group.

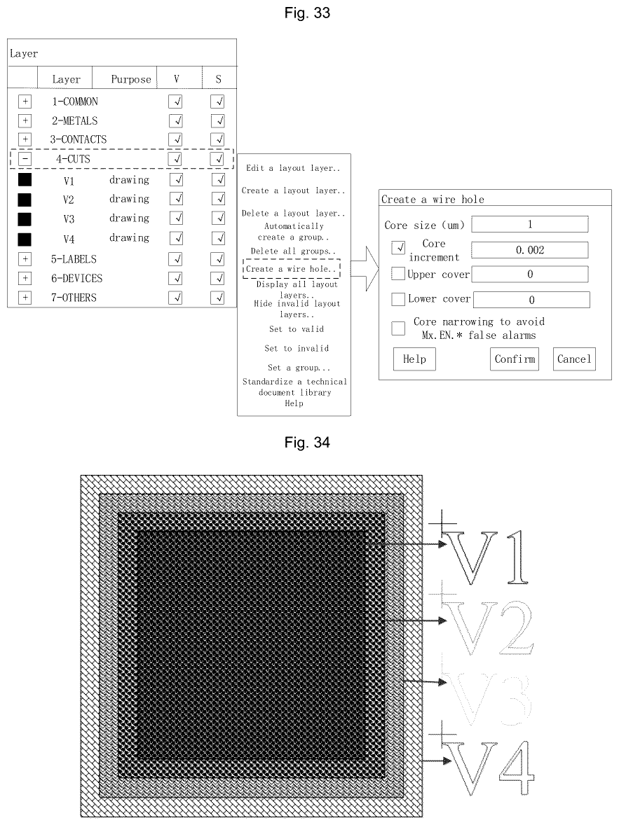

In some embodiments, the sizes of through holes may be set in batches. FIG. 33 is a schematic flowchart of an operation of setting the sizes of through holes in batches according to an embodiment of the present disclosure. As shown in FIG. 33, the following steps are included. Select a CUTS reference layer in a technical document library→right click→create a wire hole. A corresponding hole unit may be automatically added for each conventional layer under the group. In some embodiments, the sizes of patterns in the hole unit may be set the same, or with an increment as shown in FIG. 34. FIG. 34 is a schematic diagram of a core increment effect according to an embodiment of the present disclosure.

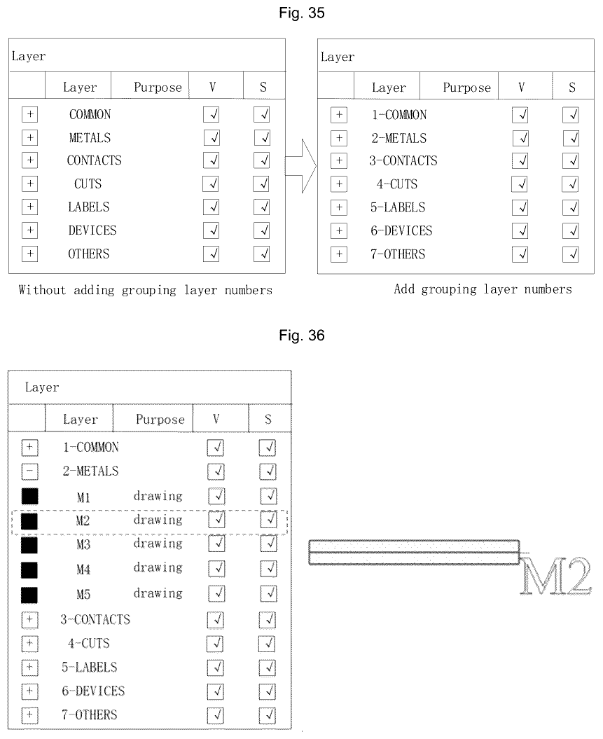

In some embodiments, the reference layers may be sorted according to the names of the reference layers. FIG. 35 is a schematic flowchart of an operation of performing sorting according to names of reference layers according to an embodiment of the present disclosure. As shown in FIG. 35, the names of the reference layers include serial numbers, such that the reference layers may be sorted according to the serial numbers.

In some embodiments, FIG. 36 is a schematic diagram of the drawing of a layout pattern in the related art according to an embodiment of the present disclosure. As shown in FIG. 36, layout patterns may be drawn in batches. In a case that the layout patterns are drawn according to related technologies, only one layer can be selected each time for drawing. The pattern drawn is the layer that is currently selected, such that the pattern is automatically displayed according to a display style of the selected layer.

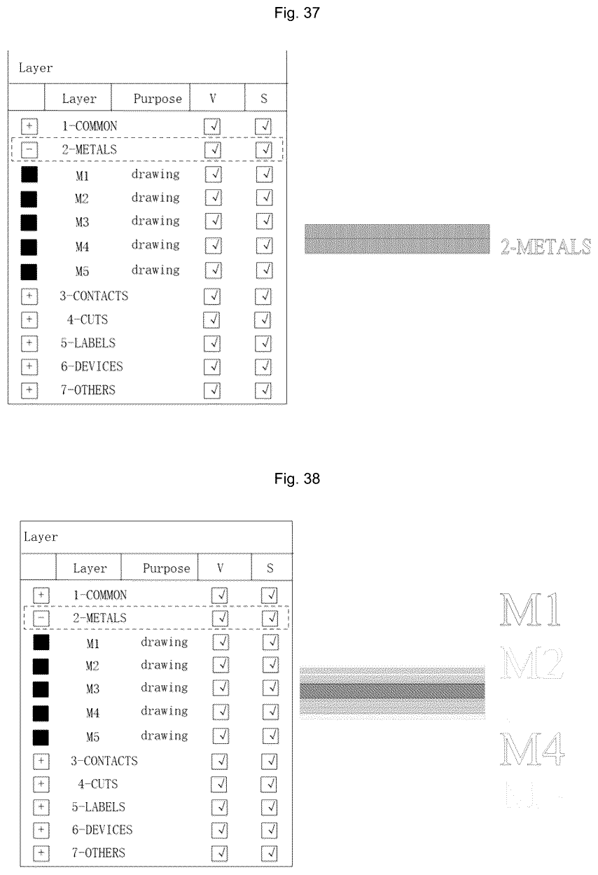

In some embodiments of the present disclosure, the reference layer is also a layout layer. FIG. 37 is a schematic diagram of the drawing of a layout pattern in a preset mode according to an embodiment of the present disclosure. As shown in FIG. 37, In a preset mode, the pattern belonging to the current reference layer may be drawn by selecting the reference layer.

In some embodiments, FIG. 38 is another schematic diagram of the drawing of a layout pattern in a preset mode according to an embodiment of the present disclosure. As shown in FIG. 38, in another preset mode, patterns belonging to the layout layers under the current reference layer group may be drawn by selecting the reference layer, that is, the reference layer is selected for drawing, then a plurality of groups of drawn patterns are generated after drawing is completed, and each group of patterns corresponds to the layout layer in the group.

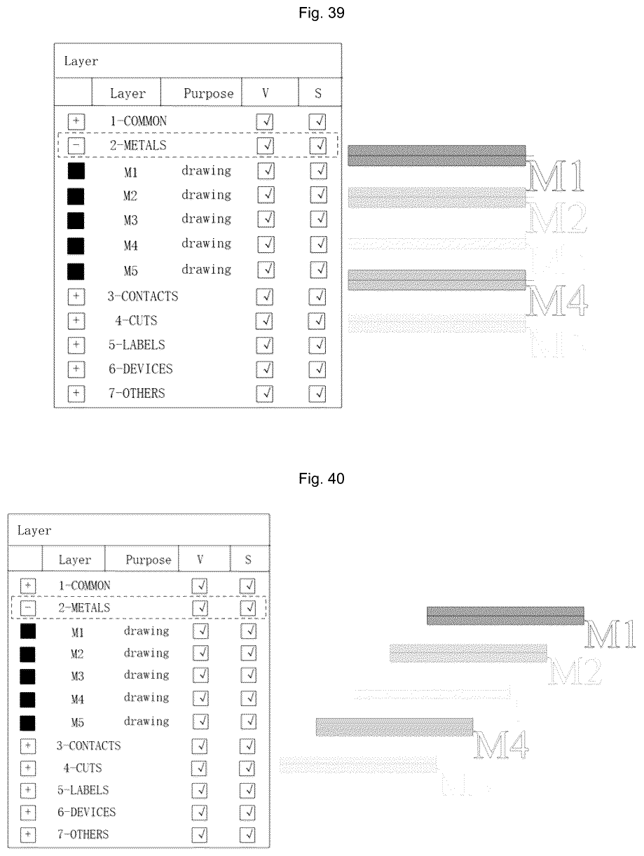

In order to prevent the plurality of groups of patterns from stacking together, a position offset between the groups and a size increment of the pattern may be preset. FIG. 39 is a schematic diagram of a layout pattern after a position offset and a size increment of a pattern according to an embodiment of the present disclosure. FIG. 40 is a schematic diagram of another layout pattern after a position offset and a size increment of a pattern according to an embodiment of the present disclosure.

In the present disclosure, classification is performed according to layout layer features and layer meanings, so as to improve classification management of the layout layers, and optimize a display effect of the layout layers, such that the layout layers may be conveniently and rapidly edited and checked.

Through the above steps, classification is performed according to layout layer features and layer meaning, so as to improve classification management of the layout layers, such that the purpose of assisting a user in conveniently and quickly checking and using the layout layers with different functions so as to improve the efficiency of the user for designing layouts. Therefore, the technical problems of low efficiency of drawing and modifying layout design caused by the need of checking relevant layout layers by dragging a scroll bar up and down in a software layer label page during checking and using of layout layers with different functions is solved.

### Embodiment 2

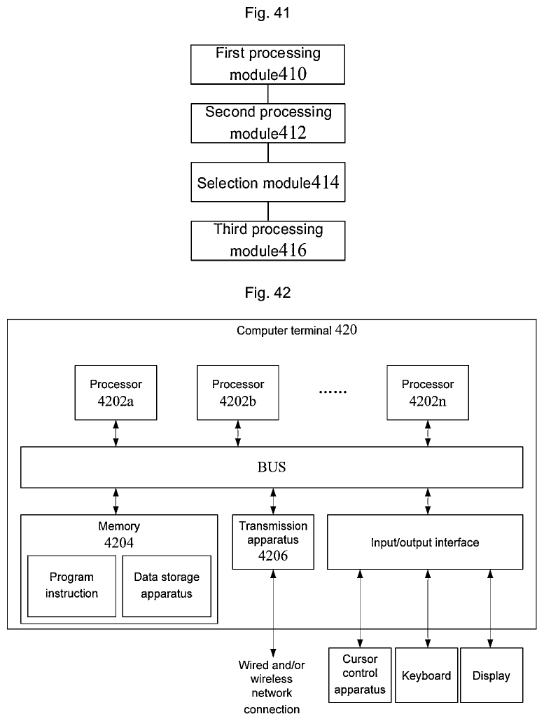

Embodiments of the present disclosure further provides an embodiment of a layout layer grouping apparatus. FIG. 41 is a schematic structural diagram of a layout layer grouping apparatus according to an embodiment of the present disclosure. As shown in FIG. 41, the apparatus includes a first processing component, a second processing component, a selection component, and a third processing component.

The first processing component 410 is configured to determine a first layout layer, and the first layout layer is a layer to be grouped.

The second processing component 412 is configured to determine a second layout layer.

The selection component 414 is configured to determine a target layout layer group according to a preset grouping rule, layer information of the first layout layer, and layer information of the second layout layer.

The third processing component 416 is configured to add the first layout layer to the target layout layer group.

It is to be noted that, each component in the layout layer grouping apparatus may be a program component (for example, a program instruction set implementing a certain specific function) or may be a hardware component. For the latter, it may be implemented in the following manners, but is not limited to the follow: each component is expressed as a processor, or, the function of each component is implemented through the processor.

It is to be noted that, the layout layer grouping apparatus provided In some embodiments may be configured to execute the method for grouping layout layer shown in FIG. 1. Therefore, the explanatory notes related to the above layout layer grouping method are also applicable In some embodiments of the present disclosure, and are not described herein again.

An embodiment of the present disclosure further provides an embodiment of a computer terminal for implementing a method for grouping layout layer. FIG. 42 is a block diagram of a hardware structure of a computer terminal (or an electronic device) configured to implement a method for grouping layout layer according to an embodiment of the present disclosure. As shown in FIG. 42, the computer terminal 420 (or electronic device 420) may include one or more (4202a, 4202b, . . . , 4202n are used to illustrate) processors (the processor may include, but is not limited to, a processing apparatus such as a microprocessor MCU or a programmable logic device FPGA), a memory 4204 for storing data, and a transmission module 4206 for a communication function. In addition, the computer terminal may further include a display, an input/output interface (I/O interface), a Universal Serial Bus (USB) port (which may be included as one of the ports of the I/O interface), a network interface, a power supply and/or a camera. Those skilled in the art may understand that the structure shown in FIG. 42 is only a schematic diagram, which does not limit the structure of the above electronic apparatus. For example, the computer terminal 420 may further include more or less components than those shown in FIG. 42, or have a different configuration from that shown in FIG. 42.

It should be noted that one or more of the above processors and/or other data processing circuits may generally be referred to herein as “data processing circuits”. The data processing circuits may be embodied in whole or in part in software, hardware, firmware, or any other combination. In addition, the data processing circuit may be a single independent processing module, or fully or partially incorporated into any of the other components of the computer terminal 420 (or electronic device). The data processing circuit acts as a processor control (for example, selection of variable resistor terminal paths connected to the interface), as mentioned In some embodiments of the present disclosure.

The memory 4204 may be configured to store software programs of application software and modules, such as a program instruction/data storage apparatus corresponding to the method for grouping layout layer in the embodiments of the present disclosure. The processor executes various function applications and data processing by running the software programs and modules stored in the memory 4204, that is, the above layout layer grouping method is implemented. The memory 4204 may include a high-speed random-access memory, and may further include a non-transitory memory, such as one or more magnetic disk memory apparatuses, a flash memory device, or other non-transitory solid-state memory devices. In some embodiments, the memory 4204 may further include memories remotely disposed relative to the processor. The remote memories may be connected to the computer terminal 420 by using a network. Examples of the above network include, but are not limited to, the Internet, an intranet, a local area network, a mobile communication network, and a combination thereof.

The transmission module 4206 is configured to receive or send data via a network. The specific example of the above network may include a wireless network provided by a communication provider of the computer terminal 420. In an example, the transmission apparatus 4206 includes a Network Interface Controller (NIC), and may be connected to other network devices by using a base station, so as to communicate with the Internet. In an example, the transmission apparatus 4206 is a Radio Frequency (RF) module, which is configured to communicate with the Internet in a wireless manner.

The display may be, for example, a touch screen Liquid Crystal Display (LCD) that enables a user to interact with a user interface of the computer terminal 420 (or electronic device).

It is noted herein that, in some optional embodiments, the computer device (electronic device) shown in FIG. 42 may include a hardware element (including a circuit), a software element (including a computer code stored on the computer-readable medium), or a combination of the hardware element and the software element. It should be noted that, FIG. 42 is merely an example of a specific example, and is intended to illustrate the types of components that may be present in the above computer device (electronic device).

It is to be noted that, the layout layer grouping electronic device shown in FIG. 42 is configured to execute the method for grouping layout layer shown in FIG. 1. Therefore, the explanatory notes related to the above layout layer grouping method are also applicable to the layout layer grouping electronic device, and are not described herein again.

Still another aspect of an embodiment of the present disclosure further provides a non-transitory storage medium. The non-transitory storage medium includes a stored computer program. A device where the non-transitory storage medium is located executes the following layout layer grouping method by running the computer program. The method includes: determining a first layout layer, where the first layout layer is a layer to be grouped; determining a second layout layer; determining a target layout layer group according to a preset grouping rule, layer information of the first layout layer, and layer information of the second layout layer; and adding the first layout layer to the target layout layer group.

The serial numbers of the foregoing embodiments of the present disclosure are merely for description, and do not represent the superiority or inferiority of the embodiments.

In the above embodiments of the present disclosure, the description of the embodiments has its own focus. For parts that are not described in detail in a certain embodiment, reference may be made to related descriptions of other embodiments.

In the several embodiments provided in the present disclosure, it should be understood that, the disclosed technical content can be implemented in other ways. The apparatus embodiments described above are merely illustrative. For example, the division of the units may be a logical function division, and there may be other divisions in actual implementation. For example, a plurality of units or components may be combined or integrated into another system, or some features can be ignored, or not implemented. In addition, the displayed or discussed mutual coupling or direct coupling or communication connection may be indirect coupling or communication connection through some interfaces, units or modules, and may be in electrical or other forms.

The units described as separate components may or may not be physically separated. The components displayed as units may or may not be physical units, that is, the components may be located in one place, or may be distributed on the plurality of units. Part or all of the units may be selected according to actual requirements to achieve the purposes of the solutions of this embodiment.

In addition, the functional units in the various embodiments of the present disclosure may be integrated into one processing unit, or each unit may exist alone physically, or two or more than two units may be integrated into one unit. The above integrated unit can be implemented in the form of hardware, or can be implemented in the form of a software functional unit.

If the integrated unit is implemented in the form of the software functional unit and sold or used as an independent product, it can be stored in the computer readable storage medium. Based on this understanding, the technical solutions of the present disclosure essentially or the parts that contribute to the prior art, all or part of the technical solutions can be embodied in the form of a software product. The computer software product is stored in a storage medium, including a plurality of instructions for causing a computer device (which may be a personal computer, a server, or a network device, and the like) to execute all or part of the steps of the method described in the various embodiments of the present disclosure. The foregoing storage medium includes a USB flash disk, a Read-Only Memory (ROM), a Random Access Memory (RAM), and various media that can store program codes, such as a mobile hard disk, a magnetic disk, or an optical disk.

The above description is merely preferred implementations of the present disclosure, and it should be noted that persons of ordinary skill in the art may also make several improvements and refinements without departing from the principle of the present disclosure, and it should be considered that these improvements and refinements shall fall within the protection scope of the present disclosure.

What is claimed is:

1. A method for grouping layout layers, comprising:
determining a first layout layer, wherein the first layout layer is a layer to be grouped;
determining a second layout layer;
determining a target layout layer group according to a preset grouping rule, layer information of the first layout layer, and layer information of the second layout layer, wherein the layer information comprises at least one of the following: a layer type and grouping information, wherein the layer type comprises a reference layer and a conventional layer, the grouping information is used for indicating a layout layer associated with the first layout layer or the second layout layer, and the reference layer is configured to perform a bulk operation on a layout layer in the corresponding target layout layer group and configured to perform an separate operation on the reference layer; and
adding the first layout layer to the target layout layer group.

2. The method for grouping layout layer as claimed in claim 1, wherein, in a case that the preset grouping rule is a first-type grouping rule, determining the target layout layer group according to the preset grouping rule, the layer information of the first layout layer, and the layer information of the second layout layer comprises:
in a case that the layer type of the second layout layer is the reference layer, determining grouping information of the first layout layer, wherein the grouping information of the first layout layer is used for indicating a fourth layout layer that has been associated with the first layout layer;
in a case that the grouping information of the first layout layer indicates that the fourth layout layer does not exist, establishing an association relationship between the first layout layer and the second layout layer, and determining a layout layer group where the second layout layer is located as the target layout layer group; and
in a case that the grouping information of the first layout layer indicates that the fourth layout layer exists, deleting an association relationship between the first layout layer and the fourth layout layer, establishing the association relationship between the first layout layer and the second layout layer, and determining the layout layer group where the second layout layer is located as the target layout layer group.

3. The method for grouping layout layer as claimed in claim 1, wherein, in a case that the preset grouping rule is a second-type grouping rule, determining the target layout layer group according to the preset grouping rule, the layer information of the first layout layer, and the layer information of the second layout layer comprises:
in a case that the layer type of the second layout layer is a non-reference layer, modifying the layer type of the second layout layer to the reference layer;
after the layer type of the second layout layer is modified to the reference layer, determining the grouping information of the first layout layer, wherein the grouping information of the first layout layer is used for indicating a fourth layout layer that has been associated with the first layout layer;
in a case that the grouping information of the first layout layer indicates that the fourth layout layer does not exist, establishing an association relationship between the first layout layer and the second layout layer, and determining a layout layer group where the second layout layer is located as the target layout layer group; and
in a case that the grouping information of the first layout layer indicates that the fourth layout layer exists, deleting an association relationship between the first layout layer and the fourth layout layer, establishing the association relationship between the first layout layer and the second layout layer, and determining the layout layer group where the second layout layer is located as the target layout layer group.

4. The method for grouping layout layer as claimed in claim 1, wherein, in a case that the preset grouping rule is a third-type grouping rule, determining the target layout layer group according to the preset grouping rule, the layer information of the first layout layer, and the layer information of the second layout layer comprises:
in a case that the grouping information of the second layout layer indicates that a third layout layer exists, establishing an association relationship between the first layout layer and the third layout layer, and determining a layout layer group where the third layout layer is located as the target layout layer group.

5. The method for grouping layout layer as claimed in claim 4, wherein establishing the association relationship between the first layout layer and the third layout layer comprises:
determining the grouping information of the first layout layer, wherein the grouping information of the first layout layer is used for indicating a fourth layout layer that has been associated with the first layout layer;
in a case that the grouping information of the first layout layer indicates that the fourth layout layer does not exist, establishing the association relationship between the first layout layer and the third layout layer; and
in a case that the grouping information of the first layout layer indicates that the fourth layout layer exists, deleting an association relationship between the first layout layer and the fourth layout layer, and establishing the association relationship between the first layout layer and the third layout layer.

6. The method for grouping layout layer as claimed in claim 1, wherein, in a case that the preset grouping rule is a fourth-type grouping rule, determining the target layout layer group according to the preset grouping rule, the layer information of the first layout layer, and the layer information of the second layout layer comprises:
in a case that the layer type of the second layout layer is the reference layer, determining the grouping information of the first layout layer, wherein the grouping information of the first layout layer is used for indicating a fourth layout layer that has been associated with the first layout layer;
in a case that the grouping information of the first layout layer indicates that the fourth layout layer does not exist, establishing an association relationship between the first layout layer and the second layout layer, and determining a layout layer group where the second layout layer is located as the target layout layer group; and
in a case that the grouping information of the first layout layer indicates that the fourth layout layer exists, establishing the association relationship between the first layout layer and the second layout layer, and determining both the layout layer group where the second layout layer is located and a layout layer group where the fourth layout layer is located as the target layout layer groups.

7. The method for grouping layout layer as claimed in claim 1, wherein, in a case that the preset grouping rule is a fifth-type grouping rule, determining the target layout layer group according to the preset grouping rule, the layer information of the first layout layer, and the layer information of the second layout layer comprises:
in a case that the layer type of the second layout layer is a non-reference layer, modifying the layer type of the second layout layer to the reference layer;
in a case that the layer type of the second layout layer is the reference layer, determining the grouping information of the first layout layer, wherein the grouping information of the first layout layer is used for indicating a fourth layout layer that has been associated with the first layout layer;
in a case that the grouping information of the first layout layer indicates that the fourth layout layer does not exist, establishing an association relationship between the first layout layer and the second layout layer, and determining a layout layer group where the second layout layer is located as the target layout layer group; and
in a case that the grouping information of the first layout layer indicates that the fourth layout layer exists, establishing the association relationship between the first layout layer and the second layout layer, and determining both the layout layer group where the second layout layer is located and a layout layer group where the fourth layout layer is located as the target layout layer groups.

8. The method for grouping layout layer as claimed in claim 1, wherein, in a case that the preset grouping rule is a sixth-type grouping rule, determining the target layout layer group according to the preset grouping rule, the layer information of the first layout layer, and the layer information of the second layout layer comprises:
in a case that the grouping information of the second layout layer indicates that a third layout layer exists, establishing an association relationship between the first layout layer and the third layout layer, and determining a layout layer group where the third layout layer is located as the target layout layer group.

9. The method for grouping layout layer as claimed in claim 8, wherein establishing the association relationship between the first layout layer and the third layout layer, and determining the layout layer group where the third layout layer is located as the target group comprises:
determining the grouping information of the first layout layer, wherein the grouping information of the first layout layer is used for indicating a fourth layout layer that has been associated with the first layout layer;
in a case that the grouping information of the first layout layer indicates that the fourth layout layer does not exist, establishing the association relationship between the first layout layer and the third layout layer, and determining the layout layer group where the third layout layer is located as the target layout layer group; and
in a case that the grouping information of the first layout layer indicates that the fourth layout layer exists, establishing the association relationship between the first layout layer and the third layout layer, and determining both the layout layer group where the third layout layer is located and a layout layer group where the fourth layout layer is located as the target layout layer groups.

10. The method for grouping layout layer as claimed in claim 1, wherein after the first layout layer is added to the target layout layer group, the method for grouping layout layer further comprises:
performing a bulk operation on at least two associated layout layers in the target layout layer.

11. The method for grouping layout layer as claimed in claim 1, wherein after the first layout layer is added to the target layout layer group, the method for grouping layout layer further comprises:
performing an operation on at least one associated layout layer in the target layout layer.

12. A device for grouping layout layer, comprising:
a first processing component, configured to determine a first layout layer, wherein the first layout layer is a layer to be grouped;
a second processing component, configured to determine a second layout layer;
a selection component, configured to determine a target layout layer group according to a preset grouping rule, layer information of the first layout layer, and layer information of the second layout layer, wherein the layer information comprises at least one of the following: a layer type and grouping information, wherein the layer type comprises a reference layer and a conventional layer, the grouping information is used for indicating a layout layer associated with the first layout layer or the second layout layer, and the reference layer is configured to perform a bulk operation on a layout layer in the corresponding target layout layer group and configured to perform an individual operation on the reference layer; and
a third processing component, configured to add the first layout layer to the target layout layer group.

13. A non-transitory storage medium, comprising a stored program, wherein the program, when being run, controls a device where the non-transitory storage medium is located to perform the method for grouping layout layer as claimed in claim 1.

14. An electronic device, comprising a processor, wherein the processor is configured to operate a program; and the method for grouping layout layer as claimed in claim 1 is performed when the program is run.

15. The method for grouping layout layer as claimed in claim 2, wherein after the first layout layer is added to the target layout layer group, the method for grouping layout layer further comprises:
performing a bulk operation on at least two associated layout layers in the target layout layer.

16. The method for grouping layout layer as claimed in claim 2, wherein after the first layout layer is added to the target layout layer group, the method for grouping layout layer further comprises:
performing an operation on at least one associated layout layer in the target layout layer.

17. The method for grouping layout layer as claimed in claim 3, wherein after the first layout layer is added to the target layout layer group, the method for grouping layout layer further comprises:
performing an operation on at least one associated layout layer in the target layout layer.

18. The method for grouping layout layer as claimed in claim 4, wherein after the first layout layer is added to the target layout layer group, the method for grouping layout layer further comprises:
performing an operation on at least one associated layout layer in the target layout layer.

19. The method for grouping layout layer as claimed in claim 6, wherein after the first layout layer is added to the target layout layer group, the method for grouping layout layer further comprises:
performing an operation on at least one associated layout layer in the target layout layer.

20. The method for grouping layout layer as claimed in claim 7, wherein after the first layout layer is added to the target layout layer group, the method for grouping layout layer further comprises:
performing an operation on at least one associated layout layer in the target layout layer.
